(19) United States
(12) Patent Application Publication
(10) Pub. No.: US 2005/0040046 A1
(43) Pub. Date: Feb. 24, 2005

(54) System for in situ seed layer remediation

(76) Inventors: Aaron Frank, Murphy, TX (US); David Gonzalez, Plano, TX (US); Basab Chatterjee, Allen, TX (US); Richard L. Guldi, Dallas, TX (US)

Correspondence Address: TEXAS INSTRUMENTS INCORPORATED, P O BOX 655474, M/S 3999, DALLAS, TX, 75265, US

(21) Appl. No.: 10/645,975

(22) Filed: Aug. 22, 2003

(51) Int. Cl. C25D 5/02; H01L 21/288

(52) U.S. Cl. 205/123

(57) ABSTRACT

The present invention provides a system for removing surface contaminants from a copper seed layer disposed upon a semiconductor substrate (210), in preparation for electrochemical deposition. An electrochemical deposition apparatus (202) is provided, having a contaminant remediation module (204) housed within. The semiconductor substrate (210) is transferred into the remediation module (204), where it is exposed in a reactive remediation system (216). Contaminants are removed from the surface of the copper seed layer, followed by an immediate transfer (212) of the substrate (210) from the remediation module (204) into a plating system (208) also housed within the electrochemical deposition apparatus (202).

### TECHNICAL FIELD OF THE INVENTION

The present invention relates generally to the field of semiconductor devices and, more particularly, to apparatus and methods for remediating seed layer surfaces during device fabrication.

### BACKGROUND OF THE INVENTION

The continual demand for enhanced integrated circuit performance has resulted in, among other things, a dramatic reduction of semiconductor device geometries, and continual efforts to optimize the performance of every substructure within any semiconductor device. A number of improvements and innovations in fabrication processes, material composition, and layout of the active circuit levels of a semiconductor device have resulted in very high-density circuit designs. Increasingly dense circuit design has not only improved a number of performance characteristics, it has also increased the importance of, and attention to, semiconductor material properties and behaviors.

The increased packing density of the integrated circuit generates numerous challenges to the semiconductor manufacturing process. Every device must be smaller without damaging the operating characteristics of the integrated circuit devices. High packing density, low heat generation, and low power consumption, with good reliability and long operation life must be maintained without any functional device degradation. Increased packing density of integrated circuits is usually accompanied by smaller feature size.

As integrated circuits become denser, the widths of interconnect layers that connect transistors and other semiconductor devices of the integrated circuit are reduced. As the widths of interconnect layers and semiconductor devices decrease, their resistance increases. As a result, semiconductor manufacturers seek to create smaller and faster devices by using, for example, a copper interconnect instead of a traditional aluminum interconnect. Unfortunately, copper is very difficult to etch in most semiconductor process flows. Therefore, damascene processes have been proposed and implemented to form copper interconnects.

Damascene methods usually involve forming a trench and/or an opening in a dielectric layer that lies beneath and on either side of the copper-containing structures. Once the trenches or openings are formed, a blanket layer of the copper-containing material is formed over the entire device. Electrochemical deposition (ECD) is typically the only practical method to form a blanket layer of copper. The thickness of such a layer must be at least as thick as the deepest trench or opening. After the trenches or openings are filled with the copper-containing material, the copper-containing material over them is removed, e.g., by chemical-mechanical polishing (CMP), so as to leave the copper-containing material in the trenches and openings but not over the dielectric or over the uppermost portion of the trench or opening.

Unfortunately, however, copper tends to be rather difficult to deposit directly on dielectric via ECD, due largely to the material properties of copper and most common dielectric materials. Often, a relatively thick layer of copper will not adhere to a dielectric in a uniform and stable manner. Obviously, this can cause a number of semiconductor yield and reliability problems. Therefore, a thin starter layer of copper—a seed layer—is usually deposited on the dielectric first. The deposition of this relatively thin layer—on the order of 100 Å-1000 Å, depending on contour of the surface—provides for more stable and uniform initial application of copper to the dielectric. Once this seed layer is in place, thicker layers of copper may be plated directly on the copper “seed”. The thicker copper adheres well to the copper “seed”, resulting—in theory—in a more uniform and stable copper plating.

Even though the seed layer approach eliminates some of the copper/dielectric interface problems, other complications arise from contamination of the seed layer. In many conventional fabrication processes, seed layer deposition and the final copper ECD are performed in different apparatus. The handling, transfer, and queuing of a substrate that has just completed seed layer deposition provides a number of potential contamination sources—airborne gases or molecular particles, for example—that can cause pits, oxidation, and other anomalies in the seed layer surface. Typically, seed layers have a very high affinity for even minute amounts of contaminants. Even if only exposed for a minimal time, the relative concentration of such contaminants on the seed layer surface can increase dramatically—causing any number of anomalies. These anomalies in the seed layer surface can disrupt or inhibit the copper ECD process. For example, certain anomalies can render the seed layer surface hydrophobic, causing voids and other unstable or incomplete copper device structures to form during a plating process. Increased yield losses, device failures, and reliability problems result.

Certain difficulties of conventional processes are illustrated now in reference to prior art FIG. 1, which depicts a conventional fabrication process 100 involving seed layer handling. A substrate 102 is removed, directly or indirectly, by an operator 104 from a first processing apparatus 106 (e.g., a sputtering system), in which a seed layer is applied to substrate 102. Operator 104 then queues substrate 102 for processing by a second processing apparatus 108 (e.g., an ECD system). During its transition from apparatus 102 to apparatus 108, substrate 102 may be exposed to a number of contaminants 110 (e.g., airborne gases or particles).

The length of time that substrate 102 is exposed to contaminants 110 can vary widely, depending upon, for example, the amount of handling involved, the queue times at each apparatus, and the physical proximity of the apparatus. At worst, substrate 102 may be exposed to contaminants 110 for extended periods of time after extensive handling. Even in a best-case scenario—where apparatus 102 and 108 are proximal to one another, and handling by operator 104 and queue times are minimized—substrate 102 is still exposed to contaminants 110 long enough to incur some anomalies.

Some attempts have been made to address the problems arising from seed layer contamination. One such attempt involves storing substrates, after seed layer deposition and prior to ECD, in an inert environment (e.g., storage in nitrogen gas). Other attempts involve cleaning or repair of the seed layer prior in a separate apparatus prior to loading the substrate into ECD apparatus. Isolation methods are effective for the period of time that a substrate is stored in isolation, but fail to address exposure and handling involved in transferring substrates into and out of storage. Often, certain cleaning approaches are ineffective for particular contaminant chemistries. Cleaning approaches can also further damage, or even remove, significant portions of the seed layer—rendering the seed layer unusable. Seed repair methods often involve some measure of re-deposition of the seed layer—adding potentially numerous and costly extra processing steps. Importantly, most all such approaches fail to eliminate the exposure of the seed layer surface to some contamination during transfer between the distinct processing apparatus involved.

As a result, there is a need for a seed layer remediation system located in situ within an ECD apparatus, providing non-destructive seed layer remediation in an easy, efficient and cost-effective manner.

### SUMMARY OF THE INVENTION

The present invention provides a versatile system, located in situ within an ECD apparatus, providing non-destructive seed layer remediation in an easy, efficient and cost-effective manner. Specifically, the present invention provides a system that remediates contaminants, and contaminant-based anomalies, from a seed layer surface in a non-destructive manner. The present invention provides an ECD apparatus (e.g., an ECD cluster tool) incorporating a remediation module. Handling systems or apparatus within the ECD apparatus are adapted to transfer a substrate, upon which a seed layer is already formed, immediately from the remediation module directly into a plating chamber and a plating bath. Handling and exposure of the seed layer surface, after remediation and prior to plating, is minimized to the greatest extent possible—virtually eliminating contaminant-based anomalies. The present invention thus renders more hydrophilic seed layers—increasing effectiveness of the ECD plating process and resulting in higher yields and fewer reliability problems when compared to existing methods and systems.

More specifically, the present invention provides a system for removing surface contaminants from a copper seed layer disposed upon a semiconductor substrate, in preparation for electrochemical deposition. An electrochemical deposition apparatus is provided, having a contaminant remediation module housed within. The semiconductor substrate is transferred into the remediation module, where it is exposed in a reactive remediation system. Contaminants are removed from the surface of the copper seed layer, followed by an immediate transfer of the substrate from the remediation module into a plating system also housed within the electrochemical deposition apparatus.

The present invention also provides an electrochemical deposition system comprising a housing having a plating system disposed within. A remediation module is disposed within the housing. A substrate transfer system is also disposed within the housing, and is adapted to transfer a substrate directly from the remediation module to the plating system.

The present invention further provides a device for performing electrochemical deposition of copper on a substrate having a copper seed layer. The device comprises a housing, having a copper plating bath disposed within. A seed layer treatment system is also disposed within the housing, and comprises a reactive environment medium. The housing also includes a substrate transfer system that is adapted to transfer the substrate directly and immediately from the reactive environment medium to the copper plating bath.

The present invention also provides a method of depositing copper upon a semiconductor substrate that includes providing a substrate having a copper seed layer formed thereon. The substrate is exposed to a reactive environment treatment, adapted to remove contaminants from an exposed surface of the copper seed layer. The substrate is immediately transferred from the reactive environment treatment to a copper plating bath, where copper is plated onto the copper seed layer utilizing the copper plating bath. The steps of exposing the substrate to a reactive environment treatment, immediately transferring the substrate, and plating copper onto the copper seed layer are performed within a single apparatus.

Other features and advantages of the present invention will be apparent to those of ordinary skill in the art upon reference to the following detailed description taken in conjunction with the accompanying drawings.

### BRIEF DESCRIPTION OF THE DRAWINGS

For a better understanding of the invention, and to show by way of example how the same may be carried into effect, reference is now made to the detailed description of the invention along with the accompanying figures in which corresponding numerals in the different figures refer to corresponding parts and in which:

FIG. 1 is an illustration of a PRIOR ART seed layer handling system; and

FIG. 2 is an illustration of one embodiment of a seed layer remediation system according to the present invention.

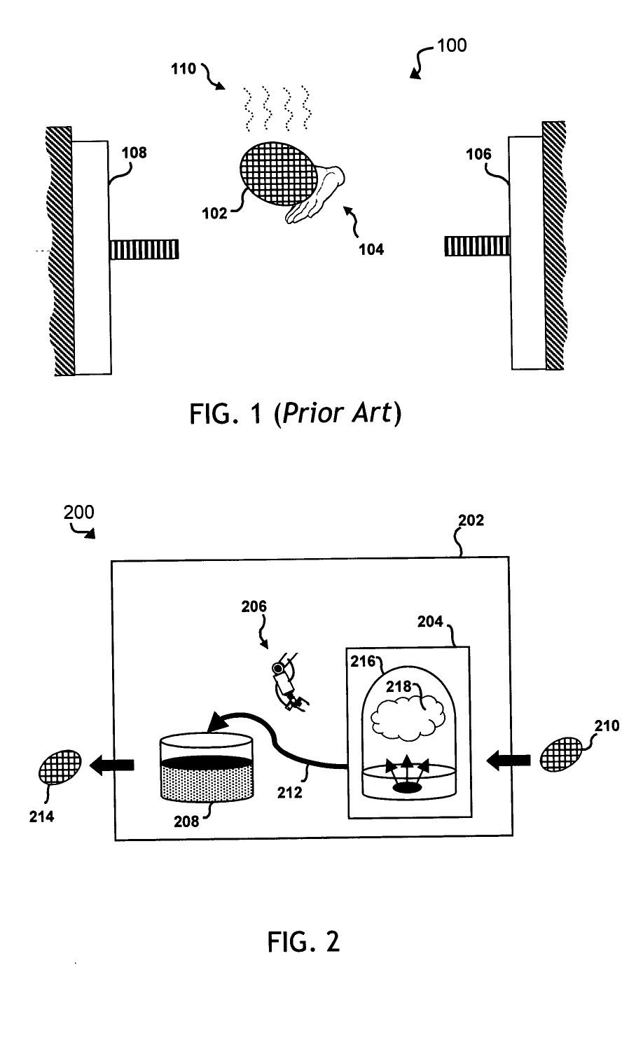

### DETAILED DESCRIPTION OF THE INVENTION

While the making and using of various embodiments of the present invention are discussed in detail below, it should be appreciated that the present invention provides many applicable inventive concepts, which can be embodied in a wide variety of specific contexts. The invention will now be described in conjunction with remediation of copper seed layers. The specific embodiments discussed herein are merely illustrative of specific ways to make and use the invention and do not limit the scope of the invention.

The present invention provides a versatile system, located in situ within an ECD apparatus, providing non-destructive seed layer remediation in an easy, efficient and cost-effective manner. The present invention recognizes that many, if not most, seed layer contamination problems stem from even the briefest exposure of the seed layer surface to ambient environment outside an ECD apparatus. The present invention further recognizes that existing processes are designed such that some significant level of seed layer exposure or handling is inherent. Most existing ECD systems are configured only for plating. Thus, any seed layer preparation—whether it is deposition, cleaning, or repair—is performed externally in a separate apparatus. Therefore, physical transfer of a substrate having a seed layer results in exposure of that seed layer to contaminants.

The present invention provides a system that remediates contaminants, and contaminant-based anomalies, from a seed layer surface in a non-destructive manner. The present invention recognizes that the non-conformal nature of ECD plating can render major problems from even minor anomalies. Relatively minor pits and protuberances caused by contamination can make significant areas on the seed layer hydrophobic (i.e., resistant to thorough and consistent wetting), resulting in defects in the copper plating (e.g., voids). The present invention recognizes that it is desirable to minimize or eliminate this phenomenon and, where possible, to improve the wetting characteristic of the seed layer surface (i.e., make it more hydrophilic). The present invention recognizes that this is especially critical where ECD processes rely on capillary filling phenomenon. The present invention further recognizes that even when such anomalies can be removed by, for example, etching or some other stripping of the seed layer surface, such methods result in an undesirable thinning or removal of the already fragile and narrow seed layer. It is therefore desirable to provide a remediation system that removes contamination while, to the greatest extent possible, preserving the seed layer or, ideally, enhancing the seed layer.

The present invention provides an ECD apparatus (e.g., an ECD cluster tool) incorporating an in situ remediation module. A handling or transfer system within the ECD apparatus transfers a seed layer substrate immediately from the remediation module directly into a plating bath within a plating chamber.

Referring now to FIG. 2, one embodiment of an in-situ seed layer remediation system 200 is illustrated. In system 200, an ECD apparatus 202 incorporates, within its housing, a remediation module 204. For purposes of explanation and illustration, apparatus 202 may be considered to be an ECD cluster tool, modified in accordance with the present invention. Apparatus 202 further comprises within its housing a transfer system 206 and a plating system 208. In most cases, apparatus 202 will also comprise within its housing a rinse chamber, which is not depicted in FIG. 2.

Transfer system 206 may comprise a robotic handling system, or any other suitable automated assembly that performs in accordance with the present invention. Furthermore, system 206 may comprise a single instance of, for example, a robotic assembly that services all operations throughout apparatus 202, or it may comprise multiple instances of similar or varying devices.

Depending upon the specific nature of apparatus 202, plating system 208 may be configured in a number of ways. System 208 may comprise a distinct plating chamber within the housing of apparatus 202, within which an appropriate plating bath system is disposed. Alternatively, system 208 may comprise just a plating bath system, enclosed only within the housing of apparatus 202. Other alternative configurations are comprehended by the present invention. For purposes of explanation and illustration, system 208 is depicted in FIG. 2 as a plating bath system enclosed within the housing of apparatus 202.

During operation of system 200, a substrate 210 having an untreated seed layer thereon is introduced into apparatus 202. System 206 moves substrate 210 into remediation module 204. After treatment of substrate 210 within module 204 is complete, system 206 makes an immediate and direct transfer 212 of the substrate 210 into plating system 208. Transfer 212 minimizes, to the greatest extent possible, the handling and exposure of substrate 210 to ambient environment outside plating system 208. After plating is complete, system 206 moves the substrate through the rinse chamber or system, if any, and delivers the now-plated substrate 214 for removal from apparatus 202.

Module 204 comprises a dedicated treatment system 216, within which a substrate 210 is exposed to a treatment medium 218. System 216 is configured to gently remove impurities and contaminants from a seed layer surface on substrate 210, while preserving the integrity of the seed layer to the greatest extent possible. Optimally, system 216 is configured to stabilize the seed layer and, where possible, restore the seed layer. For example, depending upon which treatment medium 218 is utilized, copper from the seed layer that had been lost to oxidation may be reduced back into metallic copper—rendering the seed layer more stable and resulting a plated substrate 214 of better quality and integrity.

In one embodiment of the present invention, system 216 comprises a reactive plasma treatment system. As substrate 210 is introduced into plasma system 216, it is exposed to reactive plasma 218. In one embodiment, plasma 218 comprises hydrogen plasma. In this embodiment, exposure of substrate 210 to plasma 218 removes a number of organic impurities, contaminants and other anomalies. One common anomaly is oxidation along the surface of the seed layer. In this embodiment, that oxidation may be beneficially reduced back into metallic seed layer material. Alternative embodiments comprehend plasma 218 of some other material, such as nitrogen plasma 218 or oxygen plasma 218. Composition of plasma 218 must be carefully considered, however. For example, use of oxygen plasma 218 might cause excessive oxidation of seed layer metal, due to inductively coupled heating effects. In such an embodiment, temperature must be regulated to control oxidation. Alternatively, an indirect oxygen plasma process—one where substrate exposure occurs in a chamber separated from primary electrical and magnetic fields—may be utilized if oxygen plasma is desired.

In another embodiment of the present invention, system 216 comprises an alternative, non-plasma, reactive-environment system—such as an ultraviolet (UV) atmospheric treatment system of the type described in U.S. application Ser. No. 10/xxxxxx, “System for Ultraviolet Atmospheric Seed Layer Remediation”, filed Aug. 21, 2003, and herein incorporated by reference. Within this embodiment of system 216, substrate 210 is exposed to a UV light/ozone environment 218. The UV light treatment breaks down impurities and contaminants, forming oxides that are easily burned off without extensive oxidation of the seed layer. This embodiment does not require the extensive equipment and RF power needed for the reactive plasma embodiments.

Thus, with the present invention, handling and exposure of the seed layer surface, after remediation and prior to plating, is minimized to the greatest extent possible. Contaminant-based anomalies, and the yield loss and reliability problems that result therefrom, are virtually eliminated. The present invention optimizes the cleanliness and surface integrity of the seed layer, and thus renders more hydrophilic seed layers—optimizing the interface between seed layer and ECD films. The result is increased effectiveness of the ECD plating process and higher yields when compared to existing methods and systems. Moreover, when compared to existing systems and methodologies, the present invention provides these advantages without extensive equipment supplementation and fewer operator process steps.

The embodiments and examples set forth herein are presented to best explain the present invention and its practical application and to thereby enable those skilled in the art to make and utilize the invention. However, those skilled in the art will recognize that the foregoing description and examples have been presented for the purpose of illustration and example only. The description as set forth is not intended to be exhaustive or to limit the invention to the precise form disclosed. Many modifications and variations are possible in light of the above teaching without departing from the spirit and scope of the following claims.

1. An electrochemical deposition system comprising:
a housing;
a plating system disposed within the housing;
a remediation module disposed within the housing; and
a substrate transfer system disposed within the housing and adapted to transfer a substrate directly from the remediation module to the plating system.

2. The system of claim 1, wherein the plating system comprises a plating chamber disposed within the housing, having a plating bath within.

3. The system of claim 1, wherein the plating system comprises a plating bath disposed within the housing.

4. The system of claim 1, wherein the substrate transfer system comprises a robotic handling system.

5. The system of claim 1, wherein the substrate transfer system comprises a single device instance.

6. The system of claim 1, wherein the substrate transfer system comprises multiple device instances.

7. The system of claim 1, wherein the remediation module comprises a dedicated treatment system.

8. The system of claim 7, wherein the treatment system comprises a reactive plasma system.

9. The system of claim 8, wherein the reactive plasma system comprises hydrogen plasma.

10. The system of claim 8, wherein the reactive plasma system comprises oxygen plasma.

11. The system of claim 7, wherein the treatment system comprises a non-plasma reactive environment system.

12. The system of claim 11, wherein the non-plasma reactive environment system comprises an ultraviolet ozone remediation system.

13. A device for performing electrochemical deposition of copper on a substrate having a copper seed layer, the device comprising:
a housing;
a copper plating bath disposed within the housing;
a seed layer treatment system, disposed within the housing, comprising a reactive environment medium; and
a substrate transfer system disposed within the housing and adapted to transfer the substrate directly and immediately from the reactive environment medium to the copper plating bath.

14. The device of claim 13, wherein the reactive environment system comprises a reactive plasma system.

15. The device of claim 14, wherein the reactive plasma system comprises hydrogen plasma.

16. The device of claim 14, wherein the reactive plasma system comprises oxygen plasma.

17. The device of claim 13, wherein the reactive environment system comprises a non-plasma reactive environment system.

18. A method of depositing copper upon a semiconductor substrate, comprising the steps of:
providing a substrate having a copper seed layer formed thereon;
exposing the substrate to a reactive environment treatment adapted to remove contaminants from an exposed surface of the copper seed layer;
immediately transferring the substrate from the reactive environment treatment to a copper plating bath; and
plating copper onto the copper seed layer utilizing the copper plating bath;
wherein the steps of exposing the substrate to a reactive environment treatment, immediately transferring the substrate, and plating copper onto the copper seed layer are performed within a single apparatus.

19. The method of claim 18, wherein the reactive environment treatment comprises a reactive plasma system.

20. The method of claim 18, wherein the reactive environment treatment comprises a non-plasma reactive environment system.

21. A method of removing surface contaminants from a copper seed layer disposed upon a semiconductor substrate in preparation for electrochemical deposition, comprising the steps of:
providing an electrochemical deposition apparatus having a contaminant remediation module housed within;
transferring the semiconductor substrate into the remediation module;
using the remediation module to remove contaminants from the surface of the copper seed layer; and
immediately transferring the semiconductor substrate from the remediation module into a plating system also housed within the electrochemical deposition apparatus.
